(19) United States
(12) Patent Application Publication
(10) Pub. No.: US 2026/0194721 A1
(43) Pub. Date: Jul. 9, 2026

(54) SEMICONDUCTOR DEVICE

(71) Applicant: PanelSemi Corporation, New Taipei City (TW)

(72) Inventor: Chin-Tang LI, New Taipei City (TW)

(21) Appl. No.: 19/443,389

(22) Filed: Jan. 8, 2026

Related U.S. Application Data
(60) Provisional application No. 63/742,930, filed on Jan. 8, 2025.

(51) Int. Cl. G02B 6/42; H10F 55/00; H10W 70/68; H10W 90/28

(52) U.S. Cl. CPC G02B 6/4206; G02B 6/4214; H10F 55/18; H10W 70/682; H10W 90/28

(57) ABSTRACT

A semiconductor device includes a substrate structure, a first semiconductor chip, an optoelectronic conversion element array, an optoelectronic driving circuit, a waveguide array, and an optical transmission path. The first semiconductor chip is arranged at and electrically connected to the substrate structure, and has a functional circuit. The optoelectronic conversion element array is connected to the substrate structure, and the optoelectronic driving circuit is electrically connected to the optoelectronic conversion element array and the functional circuit of the first semiconductor chip. The optoelectronic driving circuit performs electrical signal transmission and reception with the functional circuit of the first semiconductor chip. The waveguide array defines an optical coupling region, which includes multiple waveguide ports. The optical transmission path is defined between the waveguide array and the optoelectronic conversion element array, and the waveguide array corresponds to and optically couples to the optoelectronic conversion element array by the optical transmission path.

### CROSS REFERENCE TO RELATED APPLICATIONS

This Non-provisional application claims priority to U.S. provisional patent application with Ser. No. 63/742,930 filed on Jan. 8, 2025. This and all other extrinsic materials discussed herein are incorporated by reference in their entirety.

### BACKGROUND

### Technology Field

The disclosure relates to a semiconductor device capable of providing external optical communication, and particularly relates to a semiconductor device with an integrated external optical communication interface.

### Description of Related Art

As semiconductor devices require increasing data exchange with external devices, traditional electrical signal transmission interfaces have encountered bottlenecks, including limitations in transmission speed, electromagnetic interference issues, and high power consumption challenges. Consequently, the industry has begun adopting optical communication as an alternative solution. While optical communication offers advantages such as high transmission speed, strong interference resistance, and lower power consumption, integrating optical communication into semiconductor devices still presents numerous technical challenges. The current common practice is to place optoelectronic conversion modules separately adjacent to the semiconductor chip. Although this implementation is simple, it significantly increases the overall device size. Furthermore, the lengthy electrical connection paths required between the optoelectronic conversion modules and the semiconductor chip not only increase signal delay but are also susceptible to electromagnetic interference. Additionally, the alignment between optoelectronic conversion elements and waveguides remains a critical issue, as temperature variations and mechanical stress can cause alignment shifts that affect optical coupling efficiency. Existing technologies typically require complex alignment structures and packaging methods to maintain stability, which increases manufacturing costs. Therefore, how to maintain device miniaturization while ensuring stable optical coupling has become a crucial challenge faced by semiconductor devices integrating optical communication interfaces.

### SUMMARY

One aspect of this disclosure is to provide a semiconductor device and one or more exemplary embodiments thereof, all of which illustrate how this semiconductor device integrates an optical communication interface that can effectively maintain optical coupling stability.

A semiconductor device of this invention comprises a substrate structure, a first semiconductor chip, an optoelectronic conversion element array, an optoelectronic driving circuit, a waveguide array, and an optical transmission path. The substrate structure defines a first surface and a second surface opposite to the first surface. The first semiconductor chip is arranged at the substrate structure and electrically connected to the substrate structure, and the first semiconductor chip has a functional circuit. The optoelectronic conversion element array comprises a plurality of optoelectronic conversion elements and connects to the substrate structure. The optoelectronic driving circuit is electrically connected to the optoelectronic conversion element array and the functional circuit of the first semiconductor chip; the optoelectronic driving circuit performs electrical signal transmission and reception with the functional circuit of the first semiconductor chip. The waveguide array defines an optical coupling region, and the optical coupling region comprises a plurality of waveguide ports. The optical transmission path is defined between the waveguide array and the optoelectronic conversion element array. The waveguide array corresponds to and optically couples with the optoelectronic conversion element array by the optical transmission path. The optoelectronic conversion element array performs optical signal transmission (receiving signals or providing signals) corresponding to the waveguide array, and the optoelectronic conversion element array is driven by the optoelectronic driving circuit to perform conversion between optical signals and electrical signals.

In one embodiment, at least a portion of the first semiconductor chip, at least a portion of the optoelectronic driving circuit, at least a portion of the optoelectronic conversion element array, and at least a portion of the waveguide array, are arranged along a direction perpendicular to the first surface or the second surface of the substrate structure.

In one embodiment, at least a portion of the first semiconductor primary chip, at least a portion of the optoelectronic driving circuit, at least a portion of the optoelectronic conversion element array, and at least a portion of the waveguide array, are arranged sequentially along the direction perpendicular to the first surface or the second surface.

In one embodiment, the optoelectronic driving circuit is designed on a second semiconductor chip, and the second semiconductor chip and the first semiconductor chip are independent components from each other.

In one embodiment, the optoelectronic driving circuit is integrated in the first semiconductor chip.

In one embodiment, the substrate structure is an optoelectronic composite substrate, which has at least one circuit layer; the first semiconductor chip and the waveguide array are arranged on the optoelectronic composite substrate, and the first semiconductor chip is electrically connected to the circuit layer.

In one embodiment, the optoelectronic conversion element array, the optoelectronic driving circuit, and the waveguide are arranged on the optoelectronic composite substrate, and the waveguide array includes a plurality of waveguides; all of the waveguides on the optoelectronic composite substrate defines a total optical path length, and all of electrical signal lines between the first semiconductor chip and the optoelectronic driving circuit defines a total electrical circuit length, and the total optical path length is not less than 10 times of the total electrical circuit length.

In one embodiment, the optoelectronic conversion element array, the optoelectronic driving circuit and the waveguide array are arranged on the substrate structure, and the waveguide array includes a plurality of waveguides; all of the waveguides on the optoelectronic composite substrate defines a total optical path length, and the first semiconductor chip defines a long edge, the total optical path length is no less than 3 times of a length of the long edge.

In one embodiment, two adjacent optoelectronic conversion elements of the optoelectronic conversion element array defines a first average distance; the waveguide array defines a non-optical coupling region besides the optical coupling region, and the waveguide array comprises a plurality of waveguides; two adjacent waveguides in the non-optical coupling region defines a second average distance, and the second average distance is less than ½ of the first average distance.

In one embodiment, the substrate structure includes a waveguide substrate and a circuit substrate independent of each other, the waveguide array is arranged on the waveguide substrate, the circuit substrate has at least one circuit layer, and the first semiconductor chip is electrically connected to the circuit layer.

In one embodiment, the circuit substrate defines a third surface and a fourth surface opposite to the third surface, and the waveguide substrate defines a fifth surface and a sixth surface opposite to the fifth surface.

In one embodiment, the optoelectronic conversion element array includes one or more light-emitting elements.

In one embodiment, the light-emitting elements includes light emitting diode (LED), mini LED, micro LED, organic LED (OLED), or laser diode.

In one embodiment, the laser diode includes vertical cavity surface emitting laser.

In one embodiment, the optoelectronic conversion element array includes one or more photo detector elements.

In one embodiment, the photo detector elements include silicon photodiode photodetectors.

In one embodiment, the photo detector elements include compound semiconductor based photodetectors.

In one embodiment, the semiconductor device further includes an optical coupling structure corresponding to the optical transmission path; the optoelectronic conversion element array and the waveguide array are optically coupled to each other through the optical coupling structure.

In one embodiment, the optical coupling structure includes a plurality of micro lens arrays and the micro lens arrays are adjacent to the optoelectronic conversion element array.

In one embodiment, the optical coupling structure includes a plurality of micro mirror arrays, and the micro mirror arrays are adjacent to the waveguide array.

In one embodiment, the waveguide array comprises a plurality of waveguides for delivering a plurality of optical signals, and the waveguides are arranged along a direction parallel to the first surface or the second surface of the substrate structure.

In one embodiment, the waveguide array comprises a plurality of waveguides for delivering a plurality of optical signals, and the waveguides are vertically stacked along a direction along a direction perpendicular to the first surface or the second surface of the substrate structure.

In one embodiment, the waveguide array comprises a plurality of waveguides for delivering a plurality of optical signals, and some of the plurality of waveguides are arranged along a direction parallel to the first surface or the second surface of the substrate structure, and some of the plurality of waveguides are vertically stacked along a direction along a direction perpendicular to the first surface or the second surface of the substrate structure.

In one embodiment, the substrate structure comprises a window and the optical transmission path travels through the window.

In one embodiment, the optoelectronic conversion element array is arranged in the window.

In one embodiment, the optoelectronic driving circuit is adjacent to the optoelectronic conversion element array along the direction perpendicular to the first surface or the second surface of the substrate structure and is arranged in the window.

In one embodiment, the first semiconductor chip covers at least partial of the window along the direction perpendicular to the first surface or the second surface.

In one embodiment, the waveguide array and the first semiconductor chip are respectively arranged at two opposite sides of the window.

In one embodiment, the optoelectronic conversion element array includes a plurality of light-emitting elements and a plurality of photo-sensing elements, the plurality of light-emitting elements correspond to one or more waveguide ports, and the photo-sensing elements correspond to other one or more waveguide ports.

In one embodiment, the configuration between the light-emitting elements and the waveguide ports, and between the photo-sensing elements and the other waveguide ports includes a backup design; wherein different optical signals are delivered by a same waveguide port.

In one embodiment, the configuration between the light-emitting elements and the waveguide ports, and between the photo-sensing elements and the other waveguide ports includes a redundant design; wherein a same optical signal is delivered by different waveguide ports.

In one embodiment, the window is arranged at the circuit substrate, and the optical transmission path travels through the window.

In one embodiment, the waveguide array and the first semiconductor chip are respectively arranged at two opposite sides of the window of the circuit substrate.

In one embodiment, the circuit substrate defines a first coefficient of thermal expansion along a direction parallel to the third surface or the fourth surface, the waveguide substrate defines a second coefficient of thermal expansion along a direction parallel to the fifth surface or the sixth surface, and a difference between the first coefficient of thermal expansion and the second coefficient of thermal expansion is no greater than 3.

In one embodiment, the substrate structure further comprises an adhesive layer disposed between the circuit substrate and the waveguide substrate; the circuit substrate has a window, the optical transmission path travels through the window, and the adhesive layer defines a perforation corresponding to the window.

In one embodiment, the circuit substrate comprises a window, the optical transmission path travels through the window, and the optoelectronic conversion element array and waveguide array respectively at least cover two opposite sides of the window.

Accordingly, the semiconductor device of this invention can integrate an optical communication interface and effectively maintain the stability of optical coupling and the miniaturization of the overall device by the design of the optoelectronic conversion element array and waveguide array.

### BRIEF DESCRIPTION OF THE DRAWINGS

FIG. 1A and FIG. 1B are schematic diagrams of an embodiment of this invention.

FIG. 1C is a schematic diagram of another embodiment of this invention.

FIG. 1D and FIG. 1E are schematic diagrams of two other embodiments of this invention.

FIG. 2 to FIG. 9 are schematic diagrams of different embodiments of this invention.

### DETAILED DESCRIPTION OF THE DISCLOSURE

One aspect of this disclosure is to provide a semiconductor device and one or more exemplary embodiments thereof, all of which illustrate how this semiconductor device integrates an optical communication interface that can facilitate overall device miniaturization.

The following description will refer to relevant drawings to explain the stacked substrate according to the preferred embodiments of this invention, wherein the same elements will be described using the same reference symbols.

The advantages, features, and implementation methods of this disclosure will be clearly explained in the following embodiments with reference to the drawings. However, this disclosure may be embodied in various forms and should not be construed as being limited to the embodiments described herein. Rather, these embodiments are provided to make this specification thorough and complete, and to fully convey the scope of the disclosure to those skilled in the art. The scope of this disclosure should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which this disclosure pertains. Further, terms, including those defined in commonly used dictionaries, should be interpreted as having meanings consistent with their meaning in the context of the relevant art and will not be interpreted in an idealized or overly rigorous sense unless explicitly defined herein.

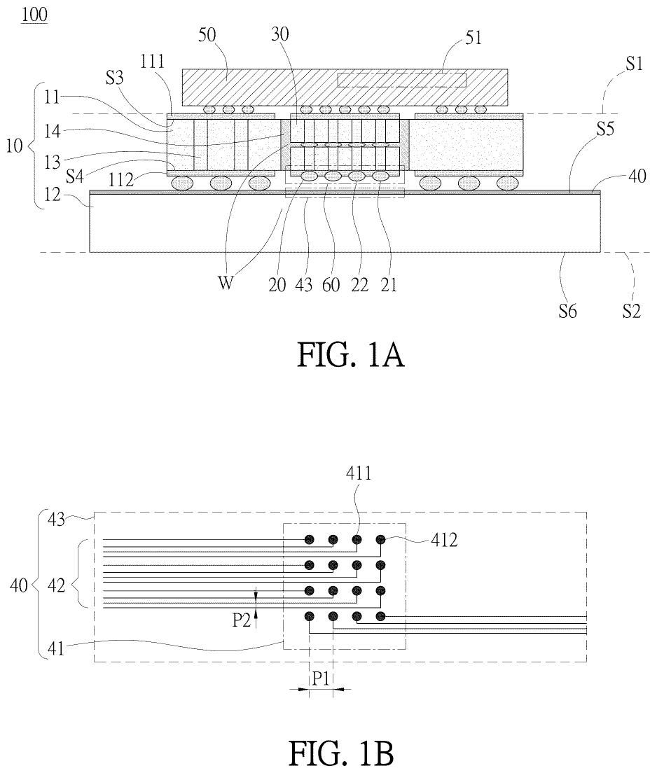

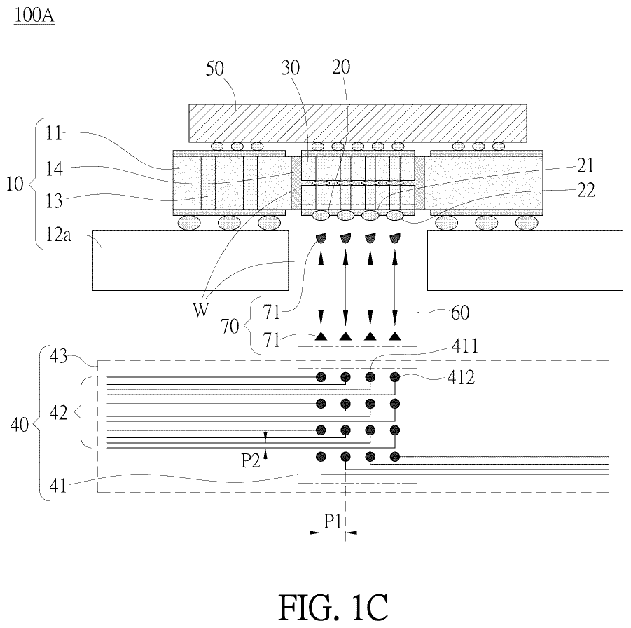

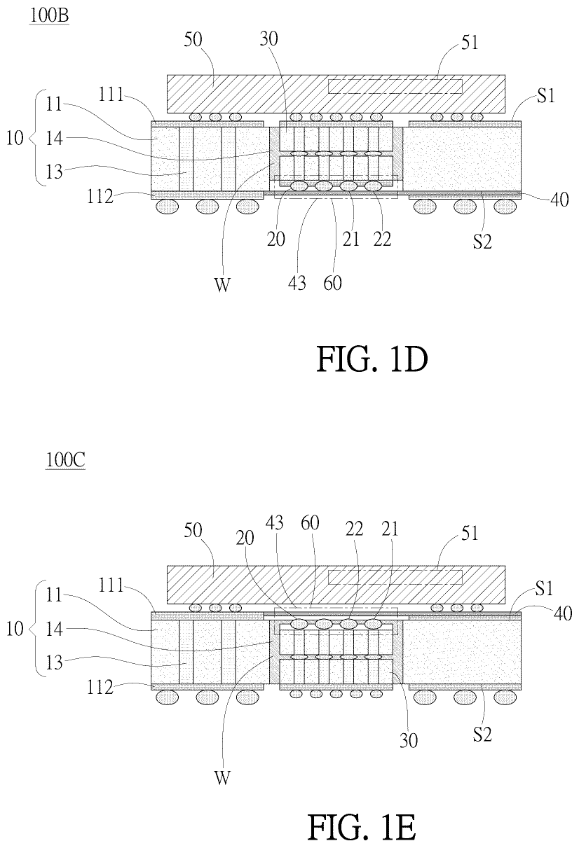

Referring to FIG. 1A, a semiconductor device 100 according to one embodiment of the present invention, includes a substrate structure 10, an optoelectronic conversion element array 20, an optoelectronic driving circuit 30, a waveguide array 40, a first semiconductor chip 50, and an optical transmission path 60. The first semiconductor primary chip 50 can be directly or indirectly connected to the substrate structure 10 and is electrically connected to the substrate structure 10, wherein the first semiconductor primary chip 50 at least has a functional circuit 51. The optoelectronic conversion element array 20 can be directly or indirectly connected to the substrate structure 10 and is directly or indirectly electrically connected to the functional circuit 51 of the semiconductor primary chip 50. The optoelectronic driving circuit 30 is electrically connected to both of the optoelectronic conversion element array 20 and the first semiconductor chip 50, wherein an electrical signal transmission and reception occurs between the optoelectronic driving circuit 30 and the functional circuit 51 of the first semiconductor chip 50. The optoelectronic conversion element array 20 includes at least a light-emitting element array 21 and a photo-sensing element array 22. The waveguide array 40 can be directly or indirectly connected to the substrate structure 10, and referring to FIG. 1B, the waveguide array 40 defines an optical coupling region 41, the optical coupling region 41 has a plurality of waveguide ports 411, 412 corresponding to the light-emitting element array 21 and the photo-sensing element array 22 respectively.

Referring to FIG. 1B, the waveguide ports 411, 412 in the optical coupling region 41 are arranged in a matrix configuration, “P1” represents a port average distance between adjacent two of the waveguide ports 411, 412 in a first direction (e.g., a horizontal direction), and “P2” represents a waveguide average distance between adjacent two waveguides 42 in a second direction (e.g., a vertical direction). It should be noted that P1 and P2 in FIG. 1B are provided merely as exemplary embodiments to illustrate average distance between the waveguide ports 411, 412 or between the waveguides 42 along different arrangement directions and are not intended to limit the average distance of the present invention to any specific direction. Accordingly, the “average distance” here recited in the specification and claims may refer to an average distance in any direction between adjacent two of the waveguide ports or waveguides elements. The optical transmission path 60 provides optical communication between the waveguide array 40 and the optoelectronic conversion element array 20. The waveguide array 40 corresponds to and optically couples with the optoelectronic conversion element array 20 by the optical transmission path 60. The optoelectronic conversion element array 20 performs optical signal transmission and reception corresponding to the waveguide array 40 and the optoelectronic conversion element array 20 is driven by the optoelectronic driving circuit 30 to perform conversion between optical and electrical signals.

The substrate structure 10 can be an optoelectronic composite substrate that integrates waveguide and circuit functions, or the substrate structure 10 comprises independent but mutually bonded waveguide substrate(s) and circuit substrate(s); and the substrate structure 10 defines a first surface S1 and a second surface S2 opposite to each other. In this embodiment, the substrate structure 10 is a composite substrate which includes a circuit substrate 11 and a waveguide substrate 12, these two substrates are independent but bonded together. The circuit substrate 11 defines a third surface S3 and a fourth surface S4 opposite to each other, and has at least one circuit layer 111 arranged on the third surface S3 or one circuit layer or 112 arranged on the fourth surfaces S4. In this embodiment, the third surface S3 and the fourth surface S4 are both provided with the circuit layer 111, 112. The substrate structure 10 further includes one or more conductive vias 13 for electrically connection of the circuit layer 111, 112, and the performance and material of the circuit substrate 11 can be designed with an intermediate layer under this situation.

The optoelectronic conversion element array 20 includes a plurality of optoelectronic conversion elements, for example, a light-emitting element array 21 for emitting optical signals and a photo-sensing element array 22 for receiving signals. The light-emitting element array 21 includes a plurality of light-emitting elements, including but not limited to micro LED elements or laser diode elements, and the laser diode can be vertical cavity surface emitting laser (VCSELs). The photo-sensing element array 22 includes a plurality of photo-sensing elements, including but not limited to silicon photodiode photodetector or compound semiconductor based photodetectors. The elements of the light-emitting element array 21 and photo-sensing element array 22 can be arranged independently or in an alternating pattern, without limitation.

As shown in FIG. 1B, the waveguide array 40 includes a plurality of waveguides 42 which form an optical transmission region 43. These waveguides 42 can be formed on the substrate structure 10 or on any layer of substrate of the substrate structure 10, or the waveguides 42 can come with their own substrate or material layer. In other words, the optical transmission region 43 can be defined as a virtual region on the substrate structure 10 or on any layer of substrate of the substrate structure 10, or the optical transmission region 43 can be a physical substrate. In this embodiment, the waveguide array 40 can be directly arranged on the fifth surface S5 of the waveguide substrate 12, with its optical coupling region 41 facing to the optoelectronic conversion element array 20. Furthermore, the waveguide array 40 can include a plurality of waveguides arranged horizontally along a direction parallel to the first surface S1 or the second surface S2 of the substrate structure 10, and these waveguides are considered as a planar waveguide, or the plurality of waveguides can be stacked vertically along a direction perpendicular to the first surface S1 or the second surface S2 of the substrate structure 10, or the waveguide array 40 includes both types of the abovementioned waveguides simultaneously.

The optoelectronic driving circuit 30 can be an independent circuit or integrated into the first semiconductor chip 50, but is not limited thereto. The first semiconductor chip 50 can include but not limited to central process unit (CPU), graphics processing unit (GPU), high bandwidth memory (HBM), and data exchanger/switching circuit.

The optical transmission path 60 provides optical communication between the waveguide array 40 and the optoelectronic conversion element array 20. The optical transmission path 60 is a virtual path but can also be formed in a window W formed in the substrate structure 10. The optoelectronic conversion element array 20 and/or the optoelectronic driving circuit 30 can also be located within the window W. In addition, a filling material 14 can be filled in the window W.

Along the optical transmission path 60, other possible optical coupling structures can be further provided besides the optoelectronic conversion element 20 array and/or the optoelectronic driving circuit 30. Referring to FIG. 1C, the semiconductor device 100A may further include an optical coupling structure 70 corresponds to the optical transmission path 60 and is arranged between the optoelectronic conversion element array 20 and the waveguide array 40 to couple optical signals therebetween. The optical coupling structure 70 includes a plurality of micro lens arrays 71 adjacent to the optoelectronic conversion element array 20, and a plurality of micro mirror arrays 72 adjacent to the waveguide array 40.

The relative relationships between the waveguide array 40 and other components are described as follows: The waveguide array 40 includes a plurality of waveguides 42, and all of the waveguides 42 of the waveguide substrate 12 defining a total optical path length, and all of the electrical signal lines between the first semiconductor chip 50 and the optoelectronic driving circuit 30 defines a total electrical circuit length, and the total optical path length is not less than 10 times of the total electrical circuit length. The waveguide array 40 includes a plurality of 42 waveguides all of the waveguides 42 on the waveguide substrate 42 defines a total optical path length, the first semiconductor primary defines a long edge, and the total optical path length is not less than 3 times of the length of the long edge. Further, the optoelectronic conversion element array 20 defines a first average distance between two adjacent optoelectronic conversion elements, and the waveguide array 40 further defines a non-optical coupling region besides the optical coupling region 41 and includes a plurality of multiple waveguides 42, and a second average distance is defined between two adjacent waveguides 42 in the non-optical coupling region; the second average distance is less than ½ of the first average distance.

In FIGS. 1C, 1D, 1E, 2-5, at least a portion of the first semiconductor chip 50, at least a portion of the optoelectronic conversion element array 20, at least a portion of the optoelectronic driving circuit 30, and at least a portion of the waveguide array 40 are arranged along the direction perpendicular to the first surface S1 or the second surface S2 of the substrate structure 10, forming a partially overlapping relationship between at least two of the abovementioned components. The arrangement order of the abovementioned components are not limited to the description above. In FIG. 1C, the waveguide array 40 is arranged outside the device, and a window W is formed in the waveguide substrate 12a of the substrate structure 10. In FIG. 1D and FIG. 1E, the waveguide array 40 can be arranged on the first surface S1 or the second surface S2 of the substrate structure 10.

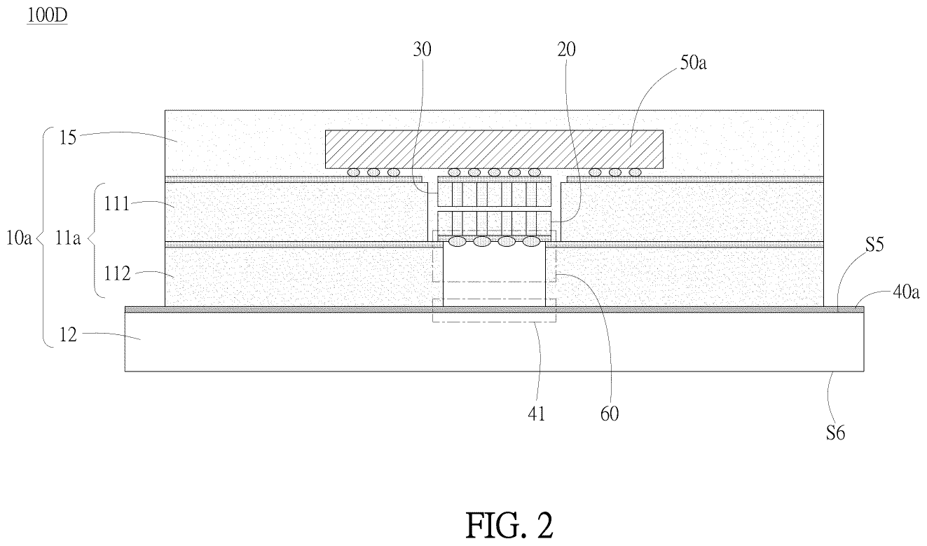

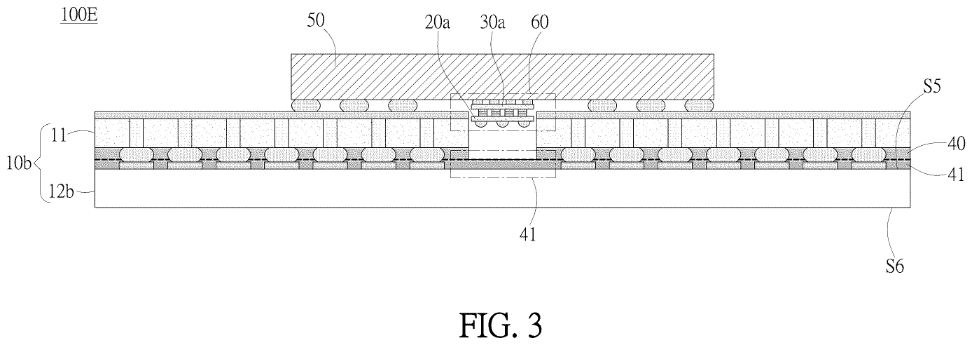

In FIG. 2, the substrate structure 10a has multi-layered substrate, and the waveguide array 40a can be arranged on the fifth surface S5 of the waveguide substrate 12. The circuit layer 111, 112 of the circuit substrate 11a are then arranged on the waveguide substrate 12 sequentially, the first semiconductor chip 50a is then arranged on the circuit substrate 11a, and a protection layer 15 covers the first semiconductor chip 50a.

In FIGS. 3-5, the waveguide array 40 is first fabricated as an intermediate layer (such as a dielectric layer) and then placed on the fifth surface S5 of waveguide substrate 12 of the substrate structure 10; the optoelectronic conversion element array 20a~20c and the optoelectronic driving circuit 30a~30c have various arrangement combinations.

In FIG. 3, the waveguide array 40 in this embodiment is formed in an intermediate layer and defines an optical coupling region 41. The optoelectronic conversion element array 20a and the optoelectronic driving circuit 30a are arranged along a direction perpendicular to the fifth surface S5 or the sixth surface S6 corresponding to the optical coupling region 41. In FIG. 3, the optoelectronic conversion element array 20a and the optoelectronic driving circuit 30a are arranged in a stacked configuration, wherein the optoelectronic driving circuit 30a is located below or above the optoelectronic conversion element array 20a. In addition, the optoelectronic driving circuit 30a is indirectly electrically connected to the first semiconductor primary chip 50 by the optoelectronic conversion element array 20a, and is not directly connected to the circuit substrate 11. With such a configuration, the electrical signals between the optoelectronic driving circuit 30a and the first semiconductor chip 50 can be transmitted by the optoelectronic conversion element array 20a, so the stacked structure is able to maintain a simplified vertical electrical interconnection path.

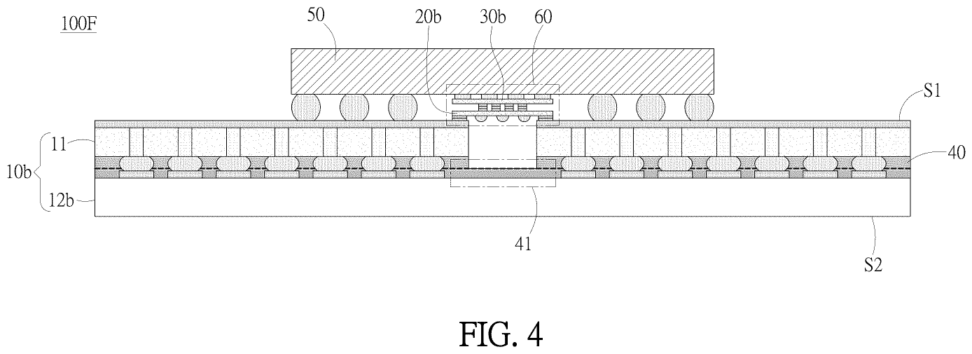

In FIG. 4, the optoelectronic conversion element array 20b and the optoelectronic driving circuit 30b of the semiconductor device 100F are both arranged along a direction of the first surface S1 or the second surface S2 and aligned with the optical coupling region 41b. Different from the semiconductor device in FIG. 3, the optoelectronic conversion element array 20b and the optoelectronic driving circuit 30b in FIG. 4 are not directly connected. The optoelectronic conversion element array 20b is connected to the circuit substrate 11 of the substrate structure 10, and the optoelectronic driving circuit 30b is directly electrically connected to the first semiconductor chip 50. In addition, the optoelectronic conversion element array 20a, 20b and the optoelectronic driving circuit 30a, 30b in FIG. 3 and FIG. 4 remain electrically connected to each other, so the optoelectronic driving circuit 30a, 30b is able to provide driving signals to the optoelectronic conversion element array 20a, 20b. With such a configuration in FIG. 3 or FIG. 4, the first semiconductor chip 50 and the circuit substrate 11 can respectively undertake different electrical functions, thereby enhancing system configuration flexibility.

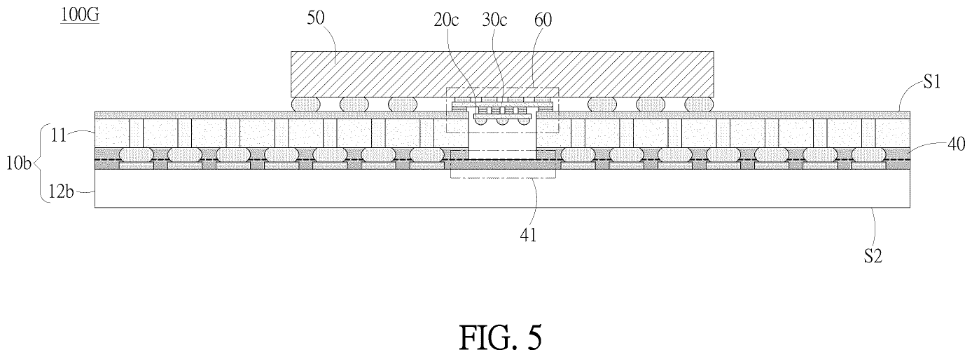

In FIG. 5, the optoelectronic conversion element array 20c and the optoelectronic driving circuit 30c of the semiconductor device 100G are arranged along a direction perpendicular to the first surface S1 or the second surface S2 of the substrate structure and aligned with the optical coupling region 41, to form a highly stacked configuration. In this embodiment, the optoelectronic driving circuit 30c is electrically connected to both the first semiconductor chip 50 and the circuit substrate 11 by the optoelectronic conversion element array 20c. That is, the optoelectronic conversion element array 20c not only serves as an optoelectronic conversion unit but also as a vertical electrical interconnection interface between the optoelectronic driving circuit 30b, the first semiconductor chip 50, and the circuit substrate 11. With such highly stacked configuration, the requirement of high-speed electric drive and stable optical coupling is satisfied simultaneously in an extremely miniaturized structure.

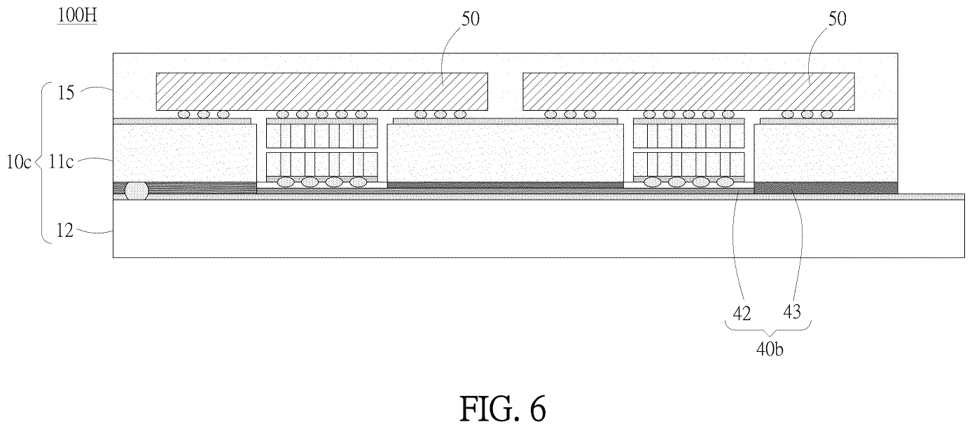

In FIG. 6, the semiconductor device 100H comprises a plurality of first semiconductor chips 50, and the substrate structure 10c is a single circuit substrate 11c, and the plurality of the first semiconductor chips 50 are arranged on the circuit substrate 11c. The circuit substrate 11c is then arranged on a single waveguide substrate 12. In this embodiment, the number of protective layers 15c corresponds to the number of the circuit substrates 11c.

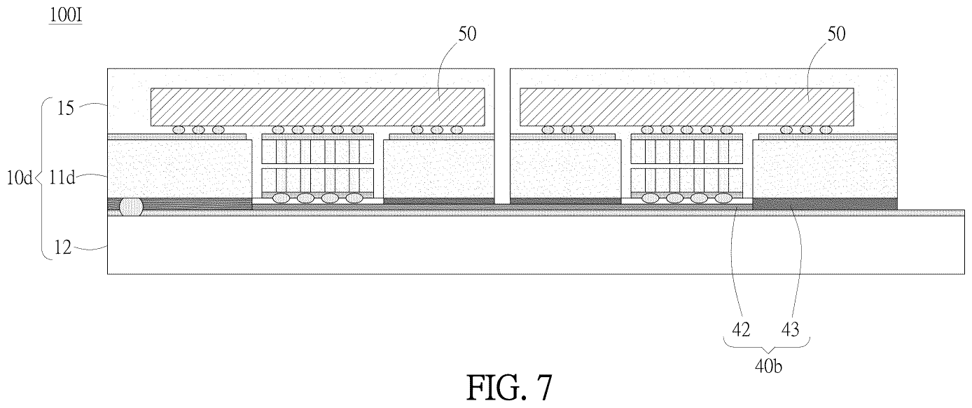

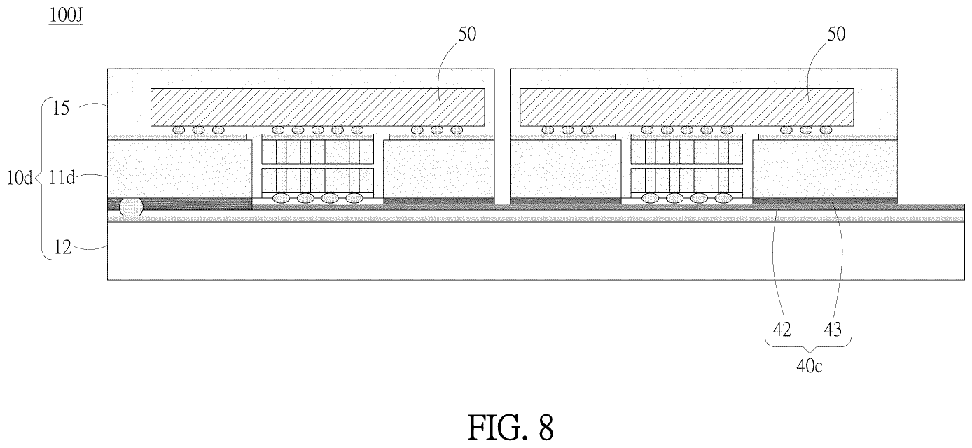

In FIG. 7, the substrate structure 10d of the semiconductor device 100I comprises a plurality of independent circuit substrates 11d, and these independent circuit substrates 11d are arranged on a single waveguide substrate 12. In this embodiment, the number of protective layers 15 corresponds to the number of the circuit substrates 11d. The difference between FIG. 8 and FIG. 7 lies in that the waveguide array 40c is fully arranged along the waveguide substrate 12 in FIG. 8, but the waveguide array 40b in FIGS. 6 and 7 which is arranged only in a partial region along the waveguide substrate 12. The full arrangement of the waveguide array 40c along the waveguide substrate 12 can be applied for a device needs longer optical paths or multiple optical coupling regions.

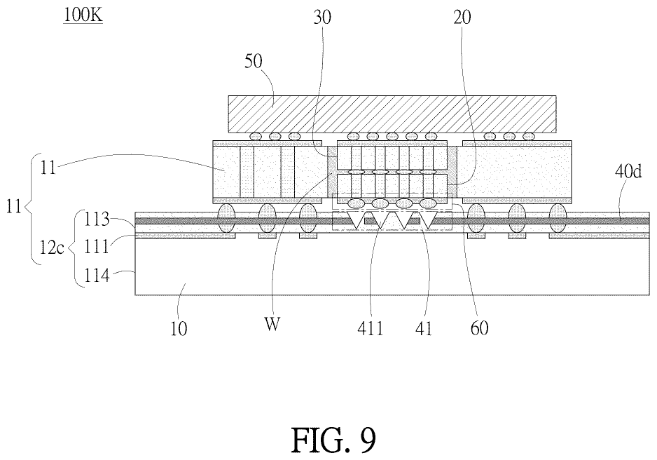

In FIG. 9, the waveguide substrate 12c of the semiconductor device 100K comprises the circuit layer 111, the substrate 114, and an intermediate layer 113. The waveguide array 40d and the circuit layer 111 are formed in an intermediate layer 113, and connected to the substrate 114. The optical coupling region 41 of the waveguide array 40d includes a plurality of waveguide ports 411, which are used to optically couple with corresponding optoelectronic elements. In this embodiment, the waveguide ports 411 may further be provided with microstructured surfaces, such as microtextures or microstructure arrays, for adjusting beam profiles or refractive conditions, thereby enhancing optical coupling efficiency between the waveguide array 40h and the corresponding optoelectronic elements. The forms and arrangements of the microstructures may be adjusted according to practical design requirements and are not limited to those illustrated.

Furthermore, the optoelectronic conversion element array 20 includes a plurality of light-emitting elements and a plurality of photo-sensing elements. The plurality of light-emitting elements correspond to one or more waveguide ports, and the photo-sensing elements correspond to other one or more waveguide ports. The configuration between the light-emitting elements and their waveguide ports, and between the photo-sensing elements and their waveguide ports, includes a backup design, which means that different optical signals can be transmitted by a same waveguide port. The configuration between the light-emitting elements and their waveguide ports, and between the photo-sensing elements and their waveguide ports also includes a redundant design, which means that a same optical signal can be transmitted by different waveguide ports.

Additionally, the circuit substrate 11 defines a first coefficient of thermal expansion along a direction parallel to the third surface S3 or the fourth surface S4, and the waveguide substrate defines a second coefficient of thermal expansion along a direction parallel to the fifth surface S5 or the sixth surface S6, where the difference between the first coefficients of thermal expansion and the second coefficients of thermal expansion is not greater than 3.

Furthermore, the substrate structure 10 includes an adhesive layer that can be arranged between the circuit substrate 11 and the waveguide substrate 12; the circuit substrate 11 has a window W, the optical transmission path 60 passes through the window W, and the adhesive layer defines a perforation corresponding to the window W.

Based on the above description, it should be understood that various embodiments of the disclosure have been described in the specification for illustrative purposes, and various modifications can be made without departing from the scope and spirit of the disclosure. Therefore, the various embodiments of the disclosure are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A semiconductor device, comprising:
a substrate structure, defining a first surface and a second surface opposite to the first surface;
a first semiconductor chip arranged at the substrate structure and electrically connected to the substrate structure, wherein the first semiconductor chip has a functional circuit;
an optoelectronic conversion element array, comprising a plurality of optoelectronic conversion elements connecting to the substrate structure;
an optoelectronic driving circuit electrically connected to the optoelectronic conversion element array and the functional circuit of the first semiconductor chip, wherein the optoelectronic driving circuit performs electrical signal transmission and reception with the functional circuit of the first semiconductor chip;
a waveguide array defining an optical coupling region, wherein the optical coupling region comprises a plurality of waveguide ports; and
an optical transmission path defined between the waveguide array and the optoelectronic conversion element array;
wherein the waveguide array corresponds to and optically couples with the optoelectronic conversion element array by the optical transmission path; the optoelectronic conversion element array performs optical signal transmission and reception corresponding to the waveguide array and is driven by the optoelectronic driving circuit to perform conversion between optical signals and electrical signals.

2. The semiconductor device of claim 1, wherein at least a portion of the first semiconductor chip, at least a portion of the optoelectronic driving circuit, at least a portion of the optoelectronic conversion element array, and at least a portion of the waveguide array are arranged along a direction perpendicular to the first surface or the second surface.

3. The semiconductor device of claim 2, wherein at least a portion of the first semiconductor primary chip, at least a portion of the optoelectronic driving circuit, at least a portion of the optoelectronic conversion element array, and at least a portion of the waveguide array are arranged sequentially along the direction perpendicular to the first surface or the second surface.

4. The semiconductor device of claim 1, wherein the optoelectronic driving circuit is designed on a second semiconductor chip, and the second semiconductor chip and the first semiconductor chip are independent components from each other.

5. The semiconductor device of claim 1, wherein the optoelectronic driving circuit is integrated into the first semiconductor primary chip.

6. The semiconductor device of claim 1, wherein the substrate structure is an optoelectronic composite substrate having at least one circuit layer; the first semiconductor primary chip and the waveguide array are arranged on the optoelectronic composite substrate, and the first semiconductor primary chip is electrically connected to the circuit layer.

7. The semiconductor device of claim 1, wherein the substrate structure comprises a waveguide substrate, and the optoelectronic conversion element array and the optoelectronic driving circuit are arranged on the waveguide substrate; the waveguide array includes a plurality of waveguides and all of the waveguides on the waveguide substrate defines a total optical path length, and all of electrical signal lines between the first semiconductor chip and the optoelectronic driving circuit defines a total electrical circuit length; and the total optical path length is not less than 10 times the total electrical circuit length.

8. The semiconductor device of claim 1, wherein the substrate structure comprises a waveguide substrate, and the optoelectronic conversion element array and the optoelectronic driving circuit are arranged on the waveguide substrate; the waveguide array a plurality of multiple waveguides and all of the waveguides on the waveguide substrate defines a total optical path length, and the first semiconductor chip defines a long edge; and the total optical path length is not less than 3 times of a length of the long edge.

9. The semiconductor device of claim 1, wherein the optoelectronic conversion element array defines a first average distance between two adjacent optoelectronic conversion elements; the waveguide array further defines a non-optical coupling region besides the optical coupling region and includes a plurality of waveguides and a second average distance is defined between two adjacent waveguides in the non-optical coupling region; and the second average distance is less than ½ of the first average distance.

10. The semiconductor device of claim 1, wherein the substrate structure includes a waveguide substrate and a circuit substrate independent of each other, the waveguide array is arranged on the waveguide substrate, the circuit substrate has at least one circuit layer, and the first semiconductor chip is electrically connected to the circuit layer.

11. The semiconductor device of claim 1, further comprising an optical coupling structure corresponding to the optical transmission path, wherein the optoelectronic conversion element array and the waveguide array are optically coupled to each other through the optical coupling structure.

12. The semiconductor device of claim 11, wherein the optical coupling structure includes a plurality of micro lens arrays, and the micro lens arrays are adjacent to the optoelectronic conversion element array.

13. The semiconductor device of claim 11, wherein the optical coupling structure includes a plurality of micro mirror arrays, and the micro mirror arrays are adjacent to the waveguide array.

14. The semiconductor device of claim 1, wherein the waveguide array includes a plurality of waveguides for delivering a plurality of optical signals, and the plurality of waveguides are vertically stacked along a vertical direction of the substrate structure.

15. The semiconductor device of claim 1, wherein the waveguide array includes a plurality of waveguides for delivering multiple optical signals; wherein a portion of the waveguides are vertically stacked along a vertical direction of the substrate structure, and another portion of the waveguides are horizontally laid along a horizontal direction of the substrate structure.

16. The semiconductor device of claim 1, wherein the optical coupling region has a plurality of waveguide ports, the optoelectronic conversion element array includes a plurality of light-emitting elements and a plurality of photo-sensing elements, the plurality of light-emitting elements correspond to one or more waveguide ports, and the photo-sensing elements correspond to other one or more waveguide ports.

17. The semiconductor device of claim 16, wherein the configuration between the light-emitting elements and the waveguide ports, and between the photo-sensing elements and the other waveguide ports includes a backup design; wherein different optical signals are delivered by a same waveguide port.

18. The semiconductor device of claim 16, wherein the configuration between the light-emitting elements and the waveguide ports, and between the photo-sensing elements and the other waveguide ports includes a redundant design; wherein a same optical signal is delivered by different waveguide ports.

19. The semiconductor device of claim 10, wherein the waveguide substrate and the first semiconductor chip are respectively disposed on opposite sides of the circuit substrate.

20. The semiconductor device of claim 10, wherein the circuit substrate defines a first coefficient of thermal expansion along a horizontal direction, the waveguide substrate defines a second coefficient of thermal expansion along the horizontal direction, and a difference between the first coefficients of thermal expansion and the second coefficients of thermal expansion is not greater than 3.
